(19) United States
(12) Patent Application Publication
(10) Pub. No.: US 2023/0194671 A1
(43) Pub. Date: Jun. 22, 2023

(54) LIGHT EMITTING DEVICE AND DISTANCE MEASURING DEVICE

(71) Applicant: Sony Semiconductor Solutions Corporation, Kanagawa (JP)

(72) Inventors: Jun Iwashita, Shizuoka (JP); Hideaki Mogi, Kanagawa (JP); Masashi Nakamura, Tokyo (JP)

(21) Appl. No.: 17/996,244

(22) PCT Filed: Apr. 22, 2021
(86) PCT No.: PCT/JP2021/016245

§ 371 Date: Oct. 14, 2022

(30) Foreign Application Priority Data
May 22, 2020 (JP) 2020-089877

(51) Int. Cl. G01S 7/481; G01S 17/08

(52) U.S. Cl. CPC G01S 7/4815; G01S 17/08

(57) ABSTRACT

There are provided a light emitting device capable of suitably forming light from a plurality of light emitting elements and a distance measuring device.

A light emitting device according to the present disclosure includes a substrate, a plurality of light emitting elements provided at a first surface of the substrate, and a plurality of lenses provided at a second surface of the substrate. The plurality of lenses includes a first lens other than a spherical lens and an ellipsoidal lens.

### TECHNICAL FIELD

The present disclosure relates to a light emitting device and a distance measuring device.

### BACKGROUND ART

A surface emitting laser such as a vertical cavity surface emitting laser (VCSEL) is known as a type of semiconductor laser. In general, a plurality of light emitting elements is provided is a two-dimensional array at a front surface or a back surface of a substrate in a light emitting device using the surface emitting laser.

### CITATION LIST

### Patent Document

Patent Document 1: Japanese Patent Application Laid-Open No. 2004-526194

### SUMMARY OF THE INVENTION

### Problems to be Solved by the Invention

In the light emitting device as described above, for example, light emitted from a plurality of light emitting elements is desirably formed into light having a desired illuminance distribution. In this case, how to form light is a problem in order to suitably form light.

Therefore, the present disclosure provides a light emitting device capable of suitably forming light from a plurality of light emitting elements, and a distance measuring device.

### Solutions to Problems

A light emitting device according to a first aspect of the present disclosure includes: a substrate; a plurality of light emitting elements provided at a first surface of the substrate; and a plurality of lenses provided at a second surface of the substrate, in which the plurality of lenses includes a first lens other than a spherical lens and an ellipsoidal lens. With this configuration, for example, light can be suitably formed. For example, light emitted from the plurality of light emitting elements can be formed into light having a desired illuminance distribution. For example, light emitted from the plurality of light emitting elements can be formed into light having a low illuminance at the central portion by the first lens other than a spherical lens and an ellipsoidal lens

Furthermore, in this first aspect, the first lens may include a lens having a single zone. With this configuration, for example, the first lens can include the later-described axicon lens, pyramidal lens, hyperboloid lens, parabolic lens, or the like.

Furthermore, in this first aspect, the first lens may include an axicon lens, a pyramidal lens, a hyperboloid lens, or a parabolic lens. With this configuration, for example, light emitted from the plurality of light emitting elements can be formed into light having a low illuminance at the central portion.

Furthermore, in this first aspect, the first lens may have a shape having an apex. With this configuration, for example, the first lens can include the aforementioned axicon lens, pyramidal lens, hyperboloid lens, parabolic lens, or the like.

Furthermore, in this first aspect, the first lens may include a lens having a plurality of zones. With this configuration, for example, the first lens can include the later-described Fresnel lens, or the like.

Furthermore, is this first aspect, the first lens may include a Fresnel lens. With this configuration, for example, light emitted from the plurality of light emitting elements can be formed into light having a low illuminance at the central portion.

Furthermore, in this first aspect, the plurality of lenses may include the first lens other than a spherical lens and an ellipsoidal lens, and a second lens having a shape different from a shape of the first lens. With this configuration, for example, light emitted from the plurality of light emitting elements can be formed into light having good uniformity of illuminance, that is, light having a small difference between the illuminance at the central portion and the illuminance at the peripheral portion, by the first and second lenses.

Furthermore, in this first aspect, the second lens may include a spherical lens or an ellipsoidal lens.

With this configuration, for example, the illuminance at the central portion is made low by the first lens, and the illuminance at the central portion is made high by the second lens, whereby light having good uniformity of illuminance can be obtained

Furthermore, in this first aspect, the plurality of lenses may have a structure that does not cause light from the light emitting element to be totally reflected. With this configuration, for example, light from the light emitting element can be emitted from the lens.

Furthermore, in this first aspect, the plurality of lenses may include at least any of a convex lens or a concave lens. With this configuration, for example, a lens can be formed by forming a convex portion or a concave portion at the second surface of the substrate by etching.

Furthermore, in this first aspect, light emitted from one of the plurality of light emitting elements may be incident on one corresponding lens. With this configuration, for example, light from the plurality of light emitting elements can be formed for each individual light emitting element.

Furthermore, in this first aspect, light emitted. from one of the plurality of light emitting elements may be incident on a corresponding plurality of lenses. With this configuration, even in a case where there are nonuniformities in performance between the light emitting elements, light can be suitably formed, and a circuit scale of a drive device as described later can be reduced, for example.

Furthermore, the light emitting device according to this first aspect may further include a refractive index buffer layer provided at the second surface of the substrate to cover the plurality of lenses, the refractive index buffer layer having a refractive index lower than a refractive index of the substrate. With this configuration, for example, the field of view of the light emitting device can be widened.

Furthermore, the light emitting device according to this first aspect may further include a drive device configured to drive the plurality of light emitting elements to cause the plurality of light emitting elements to emit light. With this configuration, for example, the operation of these light emitting elements can be controlled by the drive device.

Furthermore, in this first aspect, the drive device may be provided on the first surface side of the substrate with the plurality of light emitting elements interposed between the drive device and the substrate.

With this configuration, for example, the substrate provided with these light emitting elements can be loaded on the drive device.

Furthermore, in this first aspect, the drive device may drive the plurality of light emitting elements for each individual light emitting element. With this configuration, for example, light to be emitted from these light emitting elements can be precisely controlled.

Furthermore, in this first aspect, the drive device may scan a subject with light from the plurality of light emitting elements by sequentially driving the plurality of light emitting elements. With this configuration, for example, the light emitting device can be used for distance measurement.

Furthermore, in this first aspect, one of the plurality of lenses may receive light emitted from one corresponding light emitting element, and a position of an optical axis of at least any of lenses may be misaligned from a position of an optical axis of a corresponding light emitting element. With this configuration, for example, the direction in which light is to be emitted from the lens due to the misalignment between these optical axes.

Furthermore, in this first aspect, one of the plurality of lenses may receive light emitted from a corresponding plurality of light emitting elements. With this configuration, for example, the direction in which light is to be emitted from the lens can be changed in accordance with the position of the light emitting element.

A distance measuring device according to a second aspect of the present disclosure includes: a light emitting device configured to irradiate a subject with light; an imaging device configured to receive light reflected by the subject, to image the subject; and a control device configured to measure a distance to the subject using an image signal output from the imaging device, in which the light emitting device includes a substrate, a plurality of light emitting elements provided at a first surface of the substrate, the plurality of light emitting elements configured to emit

The light, and a plurality of lenses provided at a second surface of the substrate, the plurality of lenses configured to form the light, and the plurality of lenses includes a first lens other than a spherical lens and an ellipsoidal lens. With this configuration, for example, light for distance measurement can be suitably formed. For example, light emitted from the plurality of light emitting elements can be formed into light having a desired illuminance distribution. For example, light emitted from the plurality of light emitting elements can be formed into light having a low illuminance at the central portion by the first lens other than a spherical lens and an ellipsoidal lens.

### BRIEF DESCRIPTION OF DRAWINGS

FIG. 1 is a block diagram illustrating a configuration of a distance measuring device according to a first embodiment.

FIG. 2 is a cross-sectional view illustrating examples of a structure of the light emitting device according to the first embodiment.

FIG. 3 is a cross-sectional view illustrating a structure of the light emitting device illustrated in B of FIG. 2. FIG. 4 is a cross-sectional view illustrating examples of a structure of the light emitting device according to the first embodiment.

FIG. 5 is a perspective view and a cross-sectional view illustrating an example of a shape of a lens according to a comparative example.

FIG. 6 is a perspective view and a cross-sectional view illustrating another example of a shape of the lens according to the comparative example.

FIG. 7 is a plan view and a graph for explaining the operation of a light emitting device according to the comparative example.

FIG. 8 is a perspective view and a cross-sectional view illustrating an example of a shape of a lens according to the first embodiment.

FIG. 9 is a perspective view and a cross-sectional view illustrating another example of a shape of the lens according to the first embodiment.

FIG. 10 is a perspective view and a cross-sectional view illustrating still another example of a shape of the lens according to the first embodiment.

FIG. 11 is a perspective view and a cross-sectional view illustrating yet another example of a shape of the lens according to the first embodiment.

FIG. 12 is a plan view and a graph for explaining. the operation of the light emitting device according to the first embodiment.

FIG. 13 is a plan view and a graph for explaining the operation of a light emitting device according to a first modified example of the first embodiment.

FIG. 14 is a cross-sectional view for explaining the operation of the light emitting device according to the first modified example of the first embodiment.

FIG. 15 is a cross-sectional view illustrating a structure of a light emitting device according to a second modified example of the first embodiment.

FIG. 16 is a cross-sectional view illustrating an example of a method of manufacturing the light emitting device according to the first embodiment.

FIG. 17 is a cross-sectional view illustrating another example of a method of manufacturing the light emitting device according to the first embodiment.

FIG. 18 is a cross-sectional view illustrating still another example of a method of manufacturing the light emitting device according to the first embodiment.

FIG. 19 is a plan view (1/2) illustrating examples of die arrangement of die lenses according to the first embodiment.

FIG. 20 is a plan view (2/2) illustrating examples of the arrangement of the lens according to the first embodiment.

FIG. 21 is a cross-sectional view and a graph for explaining the workings of the lens according to the first embodiment.

FIG. 22 is a cross-sectional view for explaining the workings of the lens according to the first embodiment.

FIG. 23 is a cross-sectional view illustrating a structure of a light emitting device according to a second embodiment.

FIG. 24 a cross-sectional view and a plan view illustrating the operation of the light emitting device according to the second embodiment.

FIG. 25 is a plan view for explaining an operation example of the light emitting device according to the second embodiment.

FIG. 26 is a cross-sectional view illustrating a structure of a light emitting device according to a third embodiment.

FIG. 27 is a cross-sectional view and a plan view illustrating the operation of the light emitting device according to the third embodiment.

FIG. 28 is a plan view for explaining an operation example of the light emitting device according to the third embodiment.

### MODE FOR CARRYING OUT THE INVENTION

Hereinafter, embodiments of the present disclosure will be described with reference to the drawings.

(First Embodiment)

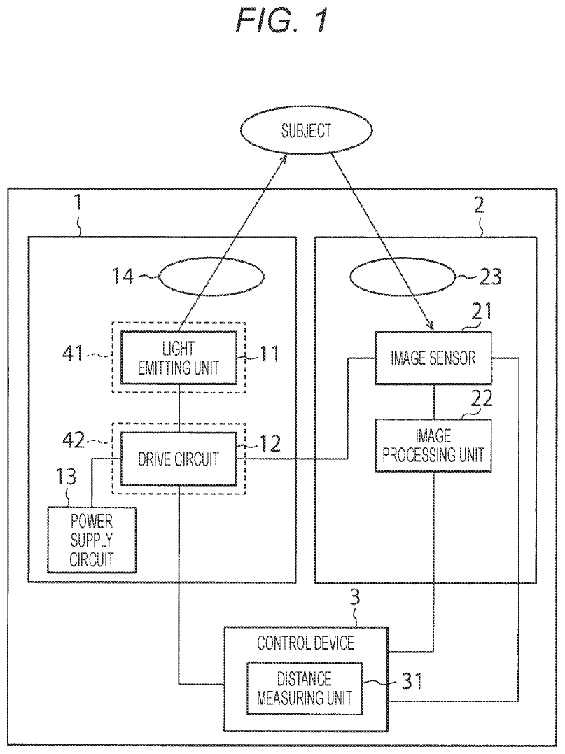

FIG. 1 is a block diagram illustrating a configuration of a distance measuring device according to a first embodiment.

The distance measuring device in FIG. 1 includes a light emitting device 1, an imaging device 2, and a control device 3. The distance measuring device in FIG.

1 irradiates a subject with light emitted from the light emitting device 1. The imaging device 2 receives light reflected by the subject and images the subject. The control device 3 measures (calculates) the distance to the subject using an image signal output from the imaging device 2. The light emitting device 1 functions as a light source for the imaging device 2 to image a subject.

The light emitting device 1 includes a light emitting unit 11, a drive circuit 12, a power supply circuit 13, and a light-emission-side optical system 14. The imaging device 2 includes an image sensor 21, an image processing unit 22, and an imaging-side optical system 23. The control device 3 includes a distance measuring unit 31.

The light emitting unit 11 emits laser light for irradiating the subject. As described later, the light emitting unit 11 according to the present embodiment includes a plurality of light emitting elements arranged in a two-dimensional array, and each light emitting element has a vertical cavity surface emitting laser (VCS) structure. The subject is irradiated with light emitted from these light emitting elements. As illustrated in FIG. 1, the light emitting unit 11 according to the present embodiment is provided in a chip called as a laser diode (LD) chip 41.

The drive circuit 12 is an electric circuit that drives the light emitting unit 11. The power supply circuit 13 is an electric circuit that generates a power supply voltage of the drive circuit 12. In the distance measuring device in FIG. 1, for example, the power supply circuit 13 generates a power supply voltage from an input voltage supplied from a battery in the distance measuring device, and the drive circuit 12 drives the light emitting unit 11 using this power supply voltage. As illustrated in FIG. 1, the drive circuit 12 according to the present embodiment is provided in a substrate called as a laser diode driver (-1,DD) substrate 42. The drive circuit 12 and the LDD substrate 42 are examples of the drive device according to the present disclosure.

The light-emission-side optical system 14 includes various optical elements, and irradiates a subject with. light from the light emitting unit 11 through these optical elements. Similarly, the imaging-side optical system 23 includes various optical elements, and receives light from the subject through these optical elements.

The image sensor 21 receives light from the subject through the imaging-side optical system 23, and converts this light into an electric signal by photoelectric conversion. The image sensor 21 is, for example, a charge coupled device (CCD) sensor or a complementary metal oxide semiconductor (CMOS) sensor. The image sensor 21 according to the present embodiment converts the electronical signal described above from an analog signal to a digital signal by analog to digital (A/D) conversion, and outputs an image signal as a digital signal to the image processing unit 22. Furthermore, the image sensor 21 according to the present embodiment outputs the frame synchronization signal to the drive circuit 12. The drive circuit 12 causes the light emitting unit 11 to emit light at timing corresponding to the frame period in the image sensor 21 on the basis of the frame synchronization signal.

The image processing unit 22 performs various types of image processing on the image signal output from the image sensor 21. The image processing unit 22 includes, for example, an image processing processor such as a digital signal processor (DSP).

The control device 3 controls various types of operation of the distance measuring device in FIG. 1, and controls, for example, light emission operation of the light emitting device 1 and imaging operation of the imaging device 2. The control device 3 includes, for example, a central processing unit (CPU) , a read only memory (ROM), a random access memory (RAM), and the like.

The distance measuring unit 31 measures the distance to the subject on the basis of the image signal output from the image sensor 21 and subjected to the image processing by the image processing unit 22. The distance measuring unit 31 employs, for example, a structured light (STL) method or a time of flight (ToF) method as the distance measurement method. The distance measuring unit 31 may further measure the distance between the distance measuring device and the subject for each portion of the subject on the basis of the image signal described above, thereby specifying the three-dimensional shape of the subject.

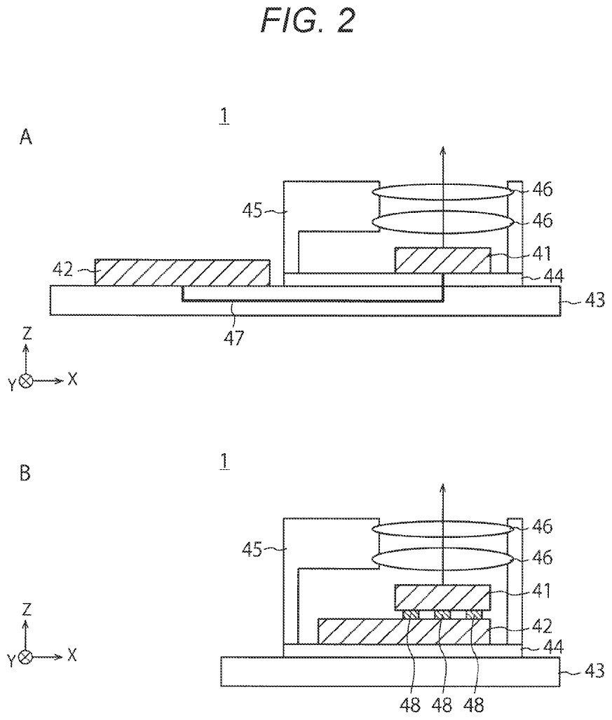

FIG. 2 is a cross-sectional view illustrating an example of a structure of the light emitting device 1 according to the first embodiment.

A of FIG. 2 illustrates a first example of the structure of the light emitting device 1 according to the present embodiment. The light emitting device 1 of this example includes the aforementioned ID chip 41 and IDD substrate 42, a mounting substrate 43, a heat dissipating substrate 44, a correction lens holder 45, one or more correction lenses 46, and a wiring line 47.

A of FIG. 2 illustrates an. X axis, a Y axis, and a Z axis perpendicular to each other. An direction and a Y direction correspond to a lateral direction (horizontal direction) , and a Z direction corresponds to a longitudinal direction (vertical direction). Furthermore, a +Z direction corresponds to the upward direction, and a −Z direction corresponds to the downward direction. The −Z direction may strictly match the gravity direction, or may not strictly match the gravity direction

The LD chip 41 is arranged on the mounting substrate 43 with the heat dissipating substrate 44 interposed therebetween, and the IDD substrate 42 is also arranged on the mounting substrate 43. The mounting substrate 43 is, for example, a printed circuit board. The image sensor 21 and the image processing unit 22 in FIG. 1 are also arranged at the mounting substrate 43 according to the present embodiment. The heat dissipating substrate 44 is, for example, a ceramic substrate such as an aluminum oxide (Al₂O₃) substrate or an aluminum nitride (AlN) substrate.

The correction lens holder 45 is arranged on the heat dissipating substrate 44 so as to surround the ID chip 41, and holds the one or more correction lenses 46 above the ID chip 41. These correction lenses 46 are included in the aforementioned light-emission-side optical system 14 (FIG. 1). Light emitted from the light emitting unit 11 (FIG. 1) in the ID chip 41 is corrected by these correction lenses 46, and thereafter, the subject (FIG. 1) is irradiated with the light. A of FIG.

2 illustrates two correction lenses 46 held by the correction lens holder 45 as an example.

The wiring line 47 is provided at the front surface and/or the back surface, in the inside, and/or the like of the mounting substrate 41, and electrically connects the ID chip 41 and the IDD substrate 42. The wiring line 47 is, for example, a printed wiring line provided at the front surface and/or the back surface of the mounting substrate 41 and a via wiring line piercing through the mounting substrate 41. Moreover, the wiring line 47 according to the present embodiment passes through the inside or the vicinity of the heat dissipating substrate 44.

B of FIG. 2 illustrates a second example of the structure of the light emitting device 1 according to the present embodiment. The light emitting device 1 of this example includes the same components as those of the light emitting device 1 of the first example, but. includes a bump 48 instead of the wiring line 47.

In B of FIG. 2, the LDD substrate 42 is arranged on the heat dissipating substrate 44, and the LD chip 41 is arranged on the LDD substrate 42. By arranging the LD chip 41 on the LDD substrate 42 in this manner, the size of the mounting substrate 44 can be reduced as compared with the case of the first example. In B of FIG. 2, the LD chip 41 is arranged on the LDD substrate 42 with the bump 48 interposed therebetween, and is electrically connected to the LDD substrate 42 by the bump 48. The bump 48 includes, for example, gold

Hereinafter, the light emitting device 1 according to the present embodiment will be described as having the structure of the second example illustrated in B of FIG. 2. However, the following description is also applicable to the light emitting device 1 having the structure of the first example except for the description regarding the structure specific to the second example.

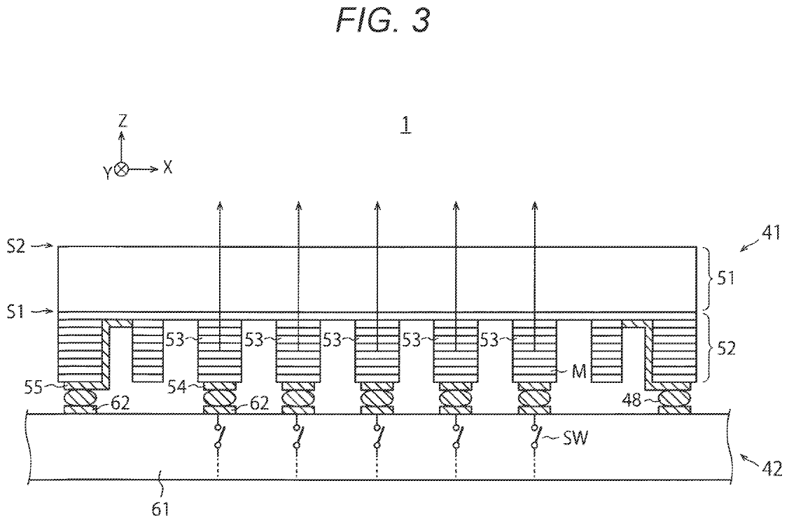

FIG. 3 is a cross-sectional view illustrating a structure of the light emitting device 1 illustrated in. B of FIG. 2.

FIG. 3 illustrates a cross section of the ID chip 41 and the IDD substrate 42 in the light emitting device 1. As illustrated in. FIG. 3, the ID chip 41 includes a substrate 51, a laminated film 52, a plurality of light emitting elements 53, a plurality of anode electrodes 54, and a plurality of cathode electrodes 55. Furthermore, the IDD substrate 42 includes a substrate 61 and a plurality of connection pads 62. Note that, in FIG. 3, illustration of a lens 71 as described later is omitted (see FIG. 4).

The substrate 51 is, for example, a compound semiconductor substrate such as a gallium arsenide (GaAs) substrate. FIG. 3 illustrates a front surface 81 of the substrate 51 facing the −Z direction and a back surface 32 of the substrate 51 facing the +Z direction. The front surface S1 is an example of a first surface according to the present disclosure. The back surface S2 is an example of a second surface according to the present disclosure.

The laminated film 52 includes a plurality of layers laminated at the front surface S1 of the substrate 51. Examples of these layers include an n-type semiconductor layer, an active layer, a p-type semiconductor layer, a light reflective layer, and an insulating layer having a light emission window. The laminated film 52 includes a plurality of mesa portions M protruding in the −Z direction. A part of these mesa portions M serves as a plurality of the light emitting elements 53.

The light emitting element 53 is provided at the front surface S1 of the substrate 51 as a part of the laminated film 52. The light emitting element 53 according to the present embodiment has a VCSEL structure and emits light in the +Z direction. As illustrated in FIG. 3, light emitted from the light emitting element 53 is transmitted through the inside of the substrate 51 from the front surface S1 to the back surface S2, and is incident on the aforementioned correction lens 46 (FIG. 2) from the substrate S1. As described above, the LD chip 41 according to the present embodiment is a back-surface-irradiation type VCSEL chip.

The anode electrode 54 is formed at the lower surface of the light emitting element 53. The cathode electrode 55 is formed at the lower surface of the mesa portion M other than the light emitting element 53, and extends from the lower surface of the mesa portion M to the lower surface of the laminated film 52 between the mesa portions M. A current flows between the corresponding anode electrode 54 and the corresponding cathode electrode 55, whereby each light emitting element 53 emits light.

As mentioned above, the LD chip 41 is arranged on the LDD substrate 42 with the bump 48 interposed therebetween, and is electrically connected to the LDD substrate 42 by the bump 48. Specifically, the connection pad 62 is formed on the substrate 61 included in the LDD substrate 42, and the mesa portion M is arranged on the connection pad 62 with the bump 48 interposed therebetween. The substrate 61 is, for example, a semiconductor substrate such as a silicon (Si) substrate. The connection pad 62 includes, for example, copper (Cu).

The LDD substrate 42 includes the drive circuit 12 that drives the light emitting unit 11 (FIG. 1). FIG. 3 schematically illustrates a plurality of switches SW included in the drive circuit 12. Each switch SW is electrically connected to the corresponding light. emitting element 53 via the bump 48. The drive circuit 12 according to the present embodiment can control (turn on and off) these switches SW for each individual switch SW. Therefore, the drive circuit 12 according to the present embodiment can drive a plurality of the light emitting elements 53 for each individual light emitting element 53. With this configuration, for example, light to be emitted from the light emitting unit 11 can be controlled precisely. For example, only the light emitting element 53 necessary for distance measurement can be allowed to emit light. Such individual control of the light emitting elements 53 can be realized by securing easy electrical connection of each light. emitting element 53 to the corresponding switch SW by arranging the LDD substrate 42 below the ID chip 41.

FIG. 4 is a cross-sectional view illustrating an example of a structure of the light emitting device 1 according to the first embodiment. Both A and B of FIG. 4 illustrate a cross section of the LD chip 41 and the LDD substrate 42 in the light emitting device 1, similarly to FIG. 3. However, in A and B of FIG. 4, illustration of the anode electrodes 54, the cathode electrodes 55, and the connection pads 62 is omitted.

In A of FIG. 4, the LD chip 41 includes the aforementioned plurality of light emitting elements 53 at the front surface S1 of the substrate 51 and a plurality of the lenses 71 at the back surface 32 of the substrate 51. Similarly to the light emitting element 53, these lenses 71 are arranged in a two-dimensional array. The lens 71 illustrated in A of FIG. 4 corresponds to the light emitting element 53 on a one-to-one basis, and each of the lenses 71 is arranged in the +Z direction of one light emitting element 53.

As illustrated in A of FIG. 4, these lenses 71 are provided as a part of the substrate 51 at the back surface S2 or the substrate 51. Specifically, these lenses 71 are convex lenses, and are formed as a part of the substrate 51 by performing etching processing on the back surface S2 of the substrate 51 into a convex shape.

According to the present embodiment, the lens 71 can be easily formed by performing etching processing on the substrate 51 to form the lens 71. Note that an example of the lens 71 other than the convex lens and an example of a processing method of the substrate 51 other than the etching processing will be described later.

The lens 71 illustrated in. A of FIG. 4 is a lens other than a spherical lens and an ellipsoidal lens, and is, for example, an axicon lens. Therefore, the lens 71 illustrated in A of FIG. 4 is formed by providing a convex portion having a conical shape (cone shape) at the back surface S2 of the substrate 51. These lenses 71 are an example of the first lens according to the present disclosure. Details of the shapes of these lenses 71 will be described later.

Light emitted from the plurality of light emitting. elements 53 described above is transmitted through the inside of the substrate 51 from the front surface S1 to the back surface S2, and is incident on the above-described plurality of lenses 71. In A of FIG. 4, light emitted from each light emitting element 53 is incident on one corresponding lens 71. With this configuration, light emitted from the plurality of light emitting elements 53 described above can be formed for each individual light emitting element 53. Light passed through the plurality of lenses 71 described above passes through the correction lens 46 (FIG. 2) and the subject (FIG. 1) is irradiated with the light.

Also in B of FIG. 4, the ID chip 41 includes the aforementioned plurality of light emitting elements 53 at the front surface S1 of the substrate 51 and a plurality of the lenses 71 at the back surface S2 of the substrate 51. Furthermore, similarly to the light emitting element 53, these lenses 71 are arranged in a two-dimensional array. However, the lenses 71 illustrated in B of FIG. 4 correspond to the light emitting element 53 on an n-to-one basis, and n lenses 71 are arranged in the direction of one light emitting element 53 (n is an integer of two or more). The value of n is 4 here, but may be another value. The shape of the lens 71 illustrated in B of FIG. 4 is similar to the shape of the lens 71 illustrated in A of FIG. 4.

Light emitted from the plurality of light emitting elements 53 described above is transmitted through the inside of the substrate 51 from the front surface S1 to the back surface S2, and is incident on the above-described plurality of lenses 71. In B of FIG. 4, light emitted from one light emitting element 53 is incident on n corresponding lenses 71. With this configuration, even in a case where there are nonuniformities in performance between the light emitting elements 53, light can be suitably formed, and a circuit scale of the LDD substrate 42 (drive circuit 12) can be reduced by, for example, reducing the number of switches SW. Light passed through the plurality of lenses 71 described above passes through the correction lens 46 (FIG. 2) and the subject (FIG. 1) is irradiated with the light.

Hereinafter, the light emitting device 1 according to the present embodiment will be described on the assumption that the lens 71 and the light emitting element 53 have an n-to-one correspondence as in the example of B of. FIG. 4 are included. However, the following description is also applicable to the light emitting device 1 having the structure of the example in A of FIG. 4 except for the description regarding the structure specific to the example in B of FIG. 4.

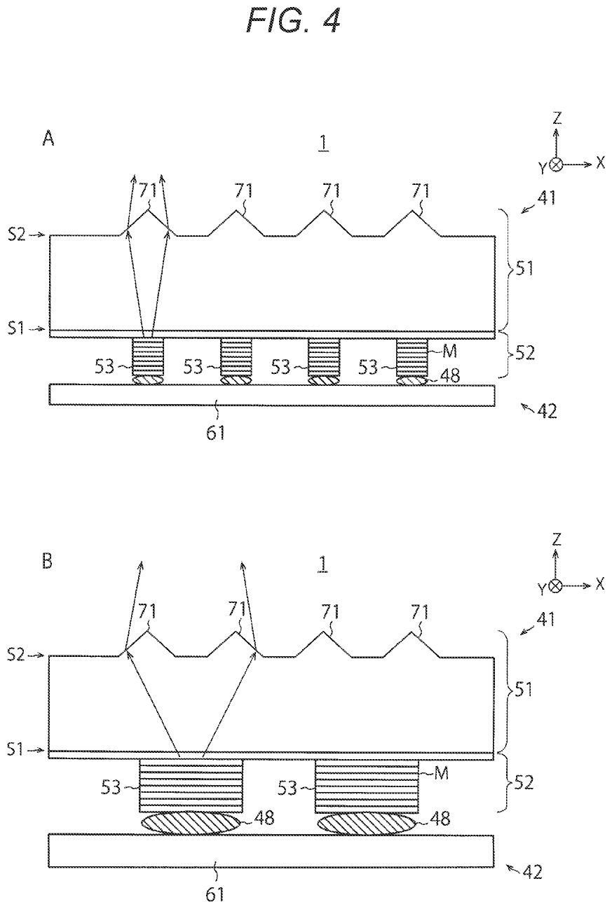

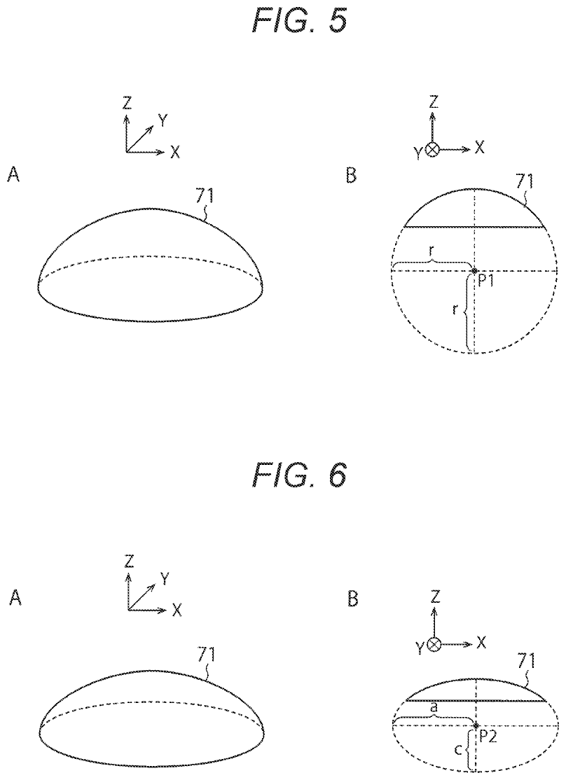

With reference to FIGS. 5 to 15, the shape of the lens 71 according to the present embodiment will be compared with the shape of the lens 71 according to a comparative example.

FIG. 5 is a perspective view and a cross-sectional view illustrating an example of a shape of the lens 71 according to the comparative example.

The lens 71 illustrated in A and B of FIG. 5 is a spherical lens. This lens 71 is formed by providing a convex portion having a shape of a part of a sphere at the back surface 32 of the substrate 51, B of FIG. 5 illustrates a center P1 and a radius r of this sphere. The radius r corresponds to the radius of curvature of this lens 71. The lens 71 illustrated in A and B of FIG.

5 desirably has a structure that does not cause light from the corresponding light emitting element 53 to be totally reflected. The optical axis of this lens 71 is parallel to the Z direction in A and B of FIG. 5, but may be non-parallel to the Z direction.

FIG. 6 is a perspective view and a cross-sectional view illustrating another example of a shape of the lens 71 according to the comparative example.

The lens 71 illustrated in A and B of FIG. 6 is an ellipsoidal lens. This lens 71 is formed by providing a convex portion having a shape of a part of an ellipsoid at the back surface S2 of the substrate 51. The shape of the ellipsoid is expressed by a mathematical formula of X²/a²+Y²/b²+Z²/c²=1. B of FIG. 6 illustrates a center P2 of this ellipsoid and a and c in the mathematical formula described above. The lens 71 illustrated in A and B of. FIG. 6 desirably has a structure that does not cause light from the corresponding light emitting element 53 to be totally reflected. The optical axis of this lens 71 is parallel to the Z direction in A and B of FIG. 6, but may be non-parallel to the Z direction.

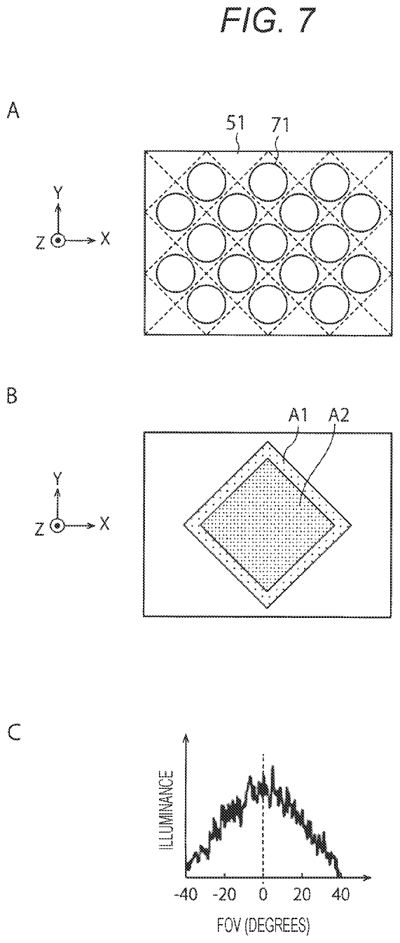

FIG. 7 is a plan view and a graph for explaining the operation of the light emitting device 1 according to the comparative example.

A of FIG. 7 illustrates a state in which a plurality of the lenses (spherical lenses) 71 having the shape illustrated in A and B of FIG. 5 is provided in a two-dimensional array at the back surface S2 of the substrate 51. In A of FIG. 7, these lenses 71 are arranged in a square lattice inclined with respect to the direction and the Y direction.

B of FIG. 7 illustrates the illuminance distribution. (illuminance profile) of light in an XY plane above these lenses 71. C of FIG. 7 illustrates one cross section (for example, an X cross section) of this illuminance distribution. In C of FIG. 7, the horizontal axis represents the field of view (FOV) of the distance measuring device, and the vertical axis represents the illuminance of light.

In a case where each lens 71 is a spherical lens, the illuminance distribution of the entire light emitted from the plurality of light emitting elements 53 described above through the plurality of lenses 71 described above has a shape as illustrated in B and. C of FIG. 7. This illuminance distribution has a shape in which the illuminance at the center portion is high and the illuminance at the peripheral portion is low. In B of FIG. 7, a region A1 where the illuminance is high (peripheral portion) is denoted by a sparse dot group, and a region A2 where the illuminance is low (center portion) is denoted by a dense dot group. The above result is similar even in a case where each lens 71 is an ellipsoidal lens.

As described above, according to the present comparative example, light having a high illuminance at the center portion is emitted from the plurality of lenses 71 described above. In a case where it is not desirable to use light having such an illuminance distribution, for example, in a case where light having such an illuminance distribution is not suitable for distance measurement, it is required to form light so as to have another illuminance distribution.

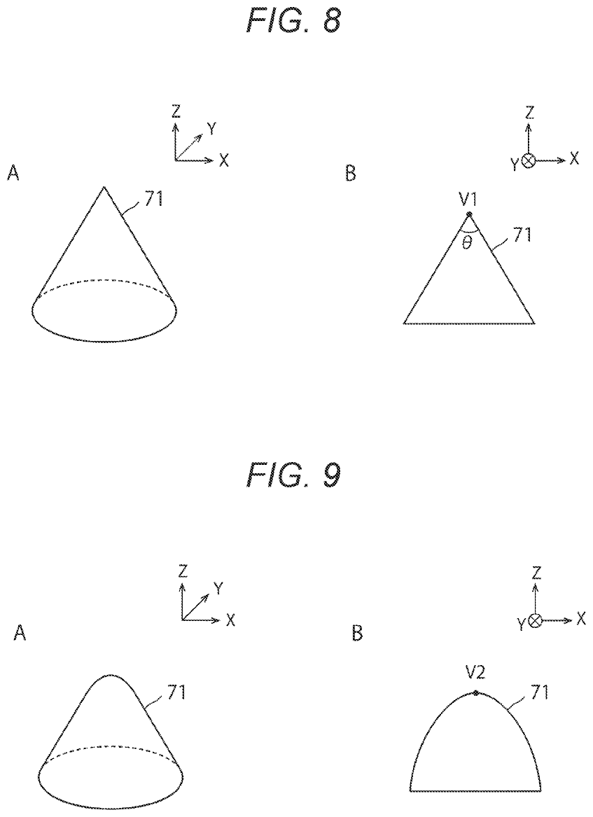

FIG. 8 is a perspective view and a cross-sectional view illustrating an example of a shape of the lens 71 according to the first embodiment.

The lens 71 illustrated in A and B of FIG. 8 is an axicon lens. This lens 71 is formed by providing a convex portion having a conical shape at the back surface 82 of the substrate 51. B of FIG. 8 illustrates an apex Vi and an apex angle 9 of this cone. The lens 71 illustrated in A and B of. FIG. 8 desirably has a structure that does not cause light from the corresponding light emitting element 53 to be totally reflected. The lens 71 without total reflection can be realized by, for example, setting the apex angle θ to 147.3 degrees or more. The optical axis of this lens 71 is parallel to the Z direction in A and B of FIG. 8, but may be non-parallel to the Z direction.

FIG. 9 is a perspective view and a cross-sectional view illustrating another example of a shape of the lens 71 according to the first embodiment.

The lens 71 illustrated in A and B of FIG. 9 is a hyperboloid lens and has a conic coefficient smaller than −1. This lens 71 is formed by providing a convex portion having a hyperboloid shape at the back surface S2 of the substrate 51. B of FIG. 9 illustrates an apex V2 of this hyperboloid. The lens 71 illustrated in A and B of FIG. 9 desirably has a structure that does not cause light from the corresponding light emitting element 53 to be totally reflected. The optical axis of this lens 71 is parallel to the Z direction in A and B of FIG. 9, but may be non-parallel to the Z direction. Furthermore, this lens 71 may be a parabolic lens instead of a hyperbola id lens.

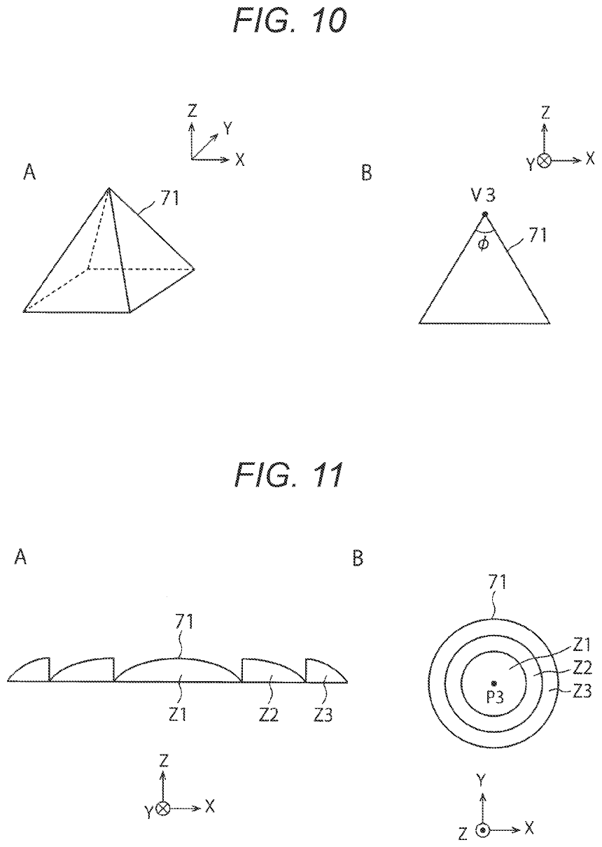

FIG. 10 is a perspective view and a cross-sectional view illustrating still another example of a shape of the lens 71 according to the first embodiment.

The lens 71 illustrated in A and B of FIG. 10 is a pyramidal lens, for example, a quadrangular pyramidal lens. This lens 71 is formed by providing a convex portion having a pyramidal shape (pyramid shape) at the back surface S2 of the substrate 51. B of FIG. 10 illustrates an apex V3 and an apex angle φ of this pyramid. The lens 71 illustrated in A and B of FIG. 10 desirably has a structure that does not cause light from the corresponding light emitting element 53 to be totally. reflected. The lens 71 without total reflection can be realized by, for example, setting the apex angle θ to the predetermined value or more. The optical axis of this lens 71 is parallel to the Z direction in A and B of FIG.

10, but may be non-parallel to the Z direction. Furthermore, this lens 71 may be a pyramidal lens instead of a quadrangular pyramidal lens.

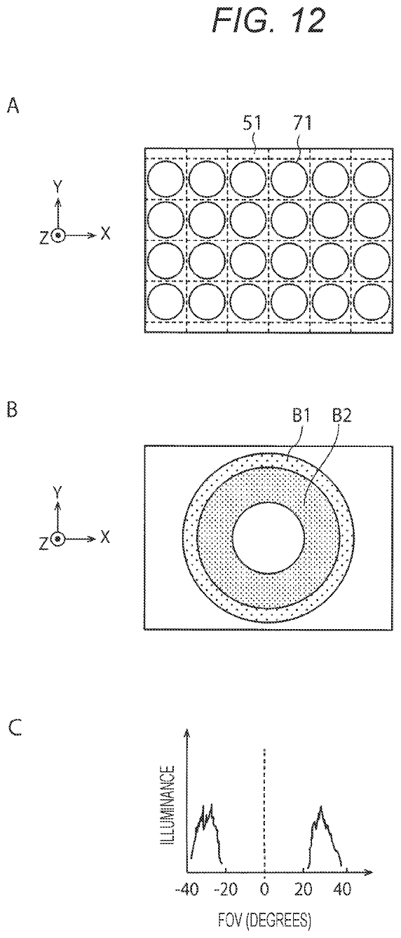

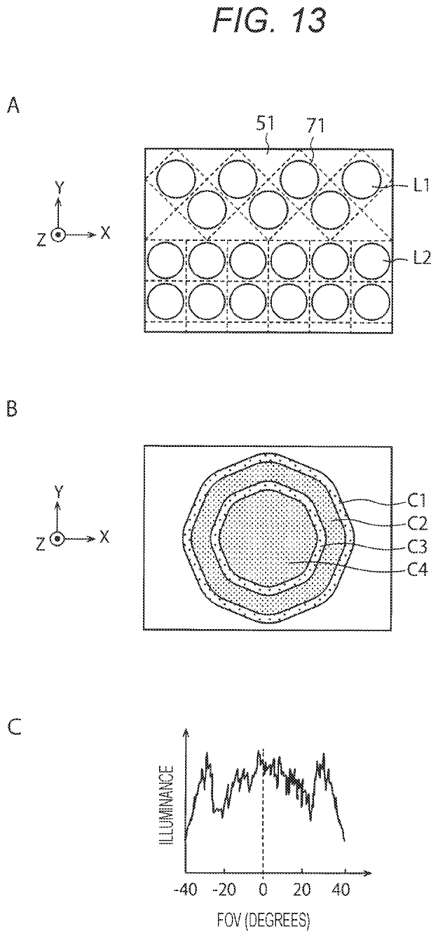

FIG. 11 is a perspective view and a cross-sectional view illustrating still another example of a shape of the lens 71 according to the first embodiment.

The lens 71 illustrated in A and B of FIG. 11 is a Fresnel lens. A and B of FIG. 11 illustrate Fresnel zones Z1 to Z3 and a center P3 of the Fresnel lens. This lens 71 is formed by providing convex portions having shapes of the Fresnel zones Z1 to Z3 at the back surface 32 of the substrate 51. The lens 71 illustrated in A and B of FIG. 11 desirably has a structure that does not cause light from the corresponding light emitting element 53 to be totally reflected. The optical axis of this lens 71 is parallel to the Z direction in A and B of FIG. 11, but may be non-parallel to the Z direction.

As described above, each lens 71 according to the present embodiment may have only a single zone as illustrated in FIGS. 8 to 10, or may have a plurality of zones as illustrated in FIG. 11. In the latter case, each lens 71 according to the present embodiment may be a lens other than the Fresnel lens.

FIG. 12 is a plan view and a graph for explaining the operation of the light emitting device 1 according to the first embodiment,

A of FIG. 12 illustrates a state in which a plurality of the lenses (axicon lens) 71 having the shape illustrated in. A and B of FIG. 8 is provided in a two-dimensional array at the back surface 52 of the substrate 51. In A of FIG. 12, these lenses 71 are arranged in a square lattice parallel to the X direction and the Y direction.

B of FIG. 12 illustrates the illuminance distribution (illuminance profile) of light in the KY plane above these lenses 71. C of FIG. 12 illustrates one cross section. (for example, an X cross section) of this illuminance distribution. In C of FIG. 12, the horizontal axis represents the field of view (FOV) of the distance measuring device, and the vertical axis represents the illuminance of light.

In a case where each lens 71 is an axicon lens, the illuminance distribution of the entire light emitted from the plurality of light emitting elements 53 described above through the plurality of lenses 71 described above has a shape as illustrated in B and C of FIG. 12. This illuminance distribution has a shape in which the illuminance at the center portion is low and the illumdnance at the peripheral portion is high. In B of FIG. 12, a region B1 where illuminance is low in the peripheral portion is denoted by a sparse dot group, and a region B2 where illuminance is high in the peripheral portion is denoted by a dense dot group. The above result is similar even in a case where each lens 71 is a hyperboloid lens, a parabolic lens, a pyramidal lens, or a Fresnel lens.

As described above, according to the present embodiment, light having a low illuminance at the center portion is emitted from the plurality of lenses 71 described above. Therefore, according to the present embodiment, it is possible to obtain light having an illuminance distribution different from the illuminance distribution that can be obtained by the spherical lens, by using the axicon lens instead of the spherical lens.

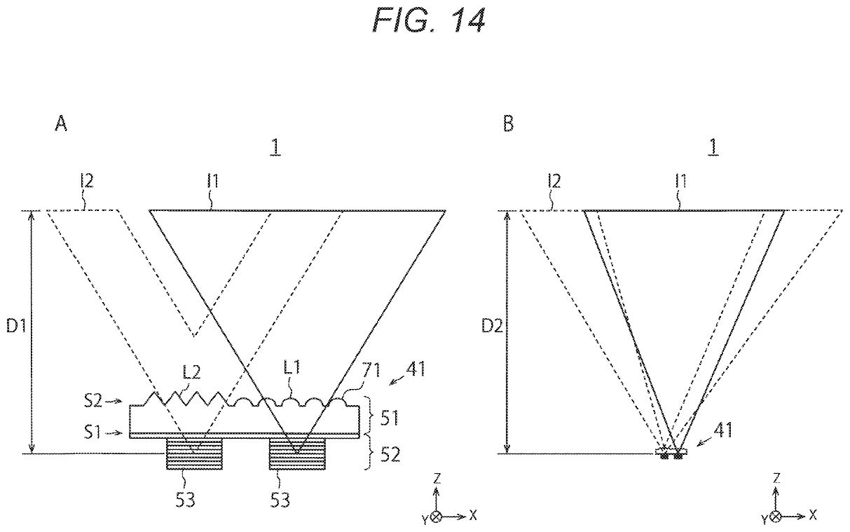

Specifically, according to the present embodiment, light having a low illuminance at the center portion can be obtained instead of light having a high illuminance at the center portion. The light according to the present embodiment can be used in an aspect as illustrated in FIGS. 13 and 14, for example.

FIG. 13 is a plan view and a graph for explaining the operation of the light emitting device 1 according to a first modified example of the first embodiment.

A of FIG. 13 illustrates a state in which a plurality of the lenses 71 is provided in a two-dimensional array at the back surface S2 of the substrate 51. These lenses 71 include a plurality of lenses L1 having the shape illustrated in A and B of FIG. 5 (spherical lenses) and a plurality of lenses 12 having the shape illustrated in A and B of FIG. 8 (axicon lenses). In A of FIG. 13, the lenses L1 are arranged in. a region on the +Y direction side of the back surface S2 of the substrate 51, and the lenses 12 are arranged in a region on the −Y direction side of the back surface S2 of the substrate 51. In addition, the lenses Li are arranged in a square lattice shape inclined with respect to the X direction and the Y direction, and the lenses 12 are arranged in a square lattice shape parallel to the X direction and the Y direction.

B of FIG. 13 illustrates the illumnance distribution (illuminance profile) of light in the XY plane above these lenses 71. C of FIG. 13 illustrates one cross section (for example, an X cross section) of this illuminance distribution. In C of FIG. 13, the horizontal axis represents the field of view (FoV) of the distance measuring device, and the vertical axis represents the illuminance of light.

In a case where the lens L1 is a spherical lens and the lens L2 is an axicon lens, the illuminance distribution of the entire light emitted from the plurality of light emitting elements 53 described above through the plurality of lenses 71 described above has a shape as illustrated in B and C of FIG. 13. This illuminance distribution has a shape in which uniformity. of illuminance is good and a difference between the illumdnance at the center portion and the illuminance at the peripheral portion is small. In B of FIG. 13, regions C1 and C3 where illuminance is low in the center portion and the peripheral portion are denoted by sparse dot groups, and regions C2 and C4 where illuminance is high in the central portion and the peripheral portion are denoted by dense dot groups. The above result is similar even in a case where the lens L1 is an ellipsoidal lens, and the lens 12 is a hyperboloid lens, a parabolic lens, a pyramidal lens, or a Fresnel lens. The lens 12 is an example of a first lens according to the present disclosure, and the lens L1 is an example of a second lens according to the present disclosure.

As described above, according to the present modified example, light having a good uniformity of illuminance is emitted from the plurality of lenses 71 described above. Therefore, according to the present modified example, it is possible to obtain light having an illuminance distribution different from the illuminance distribution that can be obtained only by the spherical lens, by using the spherical lens and the axicon lens. Specifically, according to the present modified example, light in which a difference between the illuminance at the center portion and the illuminance at the peripheral portion is small can be obtained. In general, light having good uniformity of illuminance is considered to be suitable for distance measurement.

Therefore, according to the present modified example, light can be formed so as to be suitable for distance measurement. Further details of the workings of the lens 71 according to the present modified example will be described with reference to FIG. 14.

FIG. 14 is a cross-sectional view for explaining the operation of the light emitting device 1 according to the first modified example of the first embodiment.

A of FIG. 14 illustrates a cross section of the substrate 51 and the like illustrated in A of. FIG. 13. Specifically A of FIG. 14 illustrates a plurality of the lenses L1, one light emitting element 53 corresponding to these lenses L1, a plurality of the lenses 12, and another one light emitting element 53 corresponding to these lenses 12. A of FIG. 14 further illustrates light Ii transmitted through the lens L1, light L2 transmitted through the lens 12, and a propagation distance D1 of the light II and the light I2. Similarly, B of FIG. 14 also illustrates the light I1 transmitted through the lens L1, the light 12 transmitted through the lens L2, and a propagation distance 02 of the light I1 and the light I2. However, D2>D1.

A of FIG. 14 illustrates propagation of the light II and the light 12 in a region close to the light emitting device 41 (NFP: near field pattern). On the other hand, B of FIG. 14 illustrates propagation of light II and light 12 in a region far from the light emitting device 41 (FFP: far field pattern).

As illustrated in B of FIG. 14, in the region far from the light emitting device 41, the light I1 and the light 12 can be regarded as emitted from the same point. This is the reason why the illuminance distribution illustrated in B and C of FIG. 13 can be obtained in the present modified example. The illuminance distribution illustrated in. B and C of FIG. 13 generally have a shape in which the illuminance distribution illustrated in B and C of FIG. 7 and the illuminance distribution illustrated in B and C of FIG. 12 are superimposed. This indicates that light from the plurality of lenses 71 described above according to the present modified example is obtained by superimposing the light Ii and the light I2 from the same point.

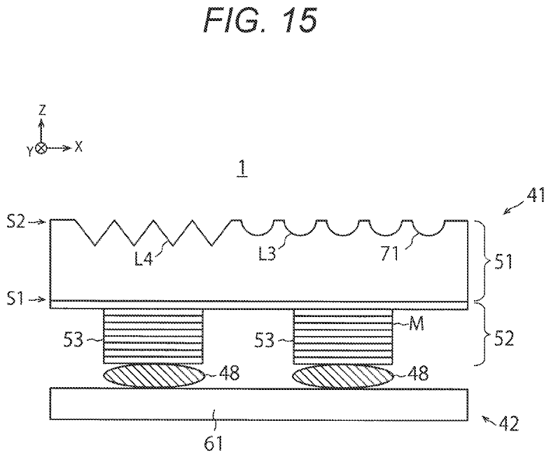

FIG. 15 is a cross-sectional view illustrating a structure of the light emitting device 1 according to a second modified example of the first embodiment.

FIG. 15 illustrates a cross section similar to A of FIG. 14. However, as illustrated in FIG. 15, the lenses 71 according to the present modified example includes a plurality of lenses 13 which is a spherical lens of a concave lens and a plurality of lenses 14 which is an axicon lens of a concave lens. In this manner, the lens 71 may be a concave lens instead of a convex lens. The lens 14 is an example of a first lens according to the present disclosure, and the lens 13 is an example of a second lens according to the present disclosure. Note that the lens 13 may be an ellipsoidal lens of a concave lens. Furthermore, the lens 14 may be a hyperboloid lens, a parabolic lens, a pyramidal lens, or a Fresnel lens, all of which are concave lenses.

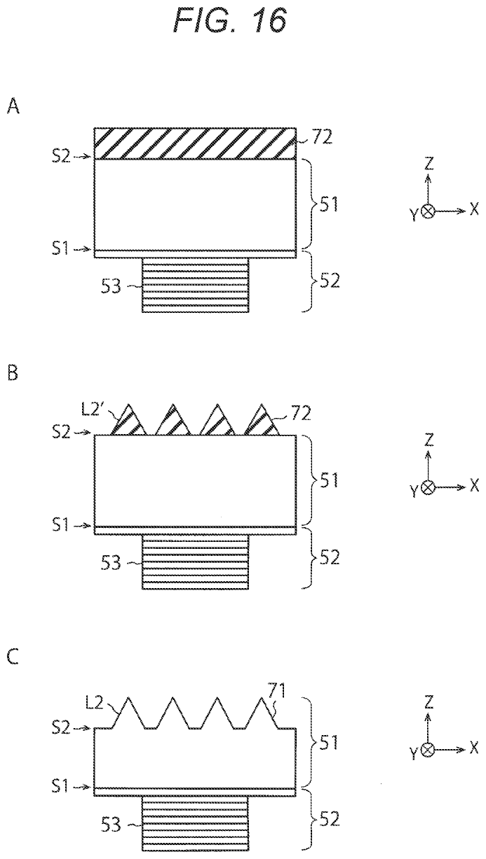

Next, a method of manufacturing the light emitting device 1 according to the present embodiment will be described with reference to FIGS. 16 to 18.

FIG. 16 is a cross-sectional view illustrating an example of a method of manufacturing the light emitting device 1 according to the first embodiment.

First, the laminated film 52, the light emitting element 53, and the like are formed at the front surface S1 of the substrate 51, and then a resist film 72 is formed at the back surface S2 of the substrate 51 (FIG. 16(a)). Next, the resist film 72 is patterned by photolithography (FIG. 16(b)). FIG. 16(b) illustrates a state in which the resist film 72 is processed into a plurality of resist patterns L2′ having a conical shape.

Next, the substrate 51 is processed by etching using the patterned resist film 72 as a mask (FIG. 16(c)). As a result, the resist pattern L2′ is transferred to the back surface 82 of the substrate 51, and a plurality of the lenses 71 is formed at the back surface 82 of the substrate 51. These lenses 71 become the lenses 12 having a conical shape (axicon lenses) by reflecting the matter in which the resist pattern L2′ has a conical shape.

Thereafter, the substrate 51 is laminated on the substrate 61 with the bumps 48 interposed therebetween (see B of FIG. 4). In this way, the light emitting device 1 according to the present embodiment is manufactured. Note that the lens 71 of this example may include a lens other than an axicon lens.

In this example, the substrate 51 is indirectly processed using the resist film 72, but the substrate 51 may be directly processed without using the resist film 72 as in the following two examples.

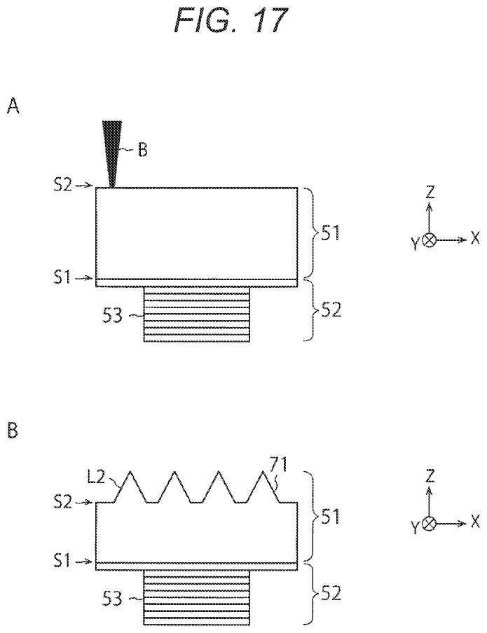

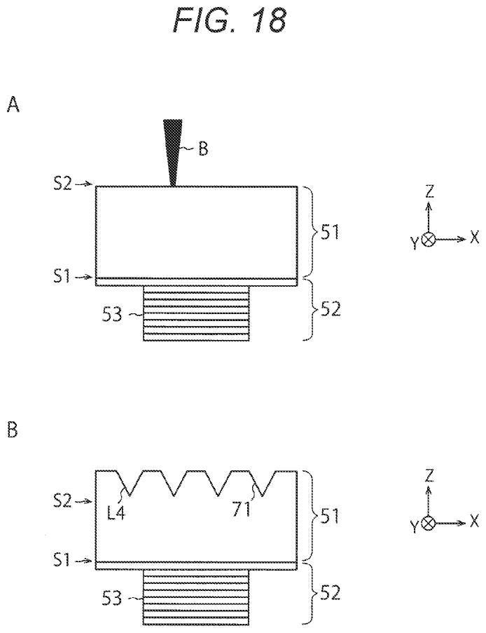

FIG. 17 is a cross-sectional view illustrating another example of a method of manufacturing the light emitting device 1 according to the first embodiment.

First, the laminated film 52, the light emitting element 53, and the like are formed at the front surface S1 of the substrate 51, and then the back surface 52 of the substrate 51 is processed with a beam B ((a) of. FIG. 17). Examples of the beam B include a laser beam and an electron beam.

In this example, a region other than the region where the lens 71 is arranged is processed with the beam B. As a result, a convex lens is formed as the lens 71 at the back surface S2 of the substrate 51 (FIG. 17(b)). The lens 71 illustrated in FIG. 17(b) is the lens 12 having a conical shape (axicon lens).

Thereafter, the substrate 51 is laminated on the substrate 61 with the bumps 48 interposed therebetween (see B of FIG. 4). In this way, the light emitting device 1 according to the present embodiment is manufactured. Note that the lens 71 of this example may include a lens other than an axicon lens.

FIG. 18 is a cross-sectional view illustrating still another example of a method of manufacturing the light emitting device 1 according to the first embodiment.

First, the laminated film 52, the light emitting element 53, and the like are formed at the front surface S1 of the substrate 51, and then the back surface S2 of the substrate 51 is processed with the beam B ((a) of FIG. 18). Examples of the beam B include a laser beam and an electron beam.

In this example, the region where the lens 71 is arranged is processed with the beam B. As a result, a concave lens is formed as the lens 71 at the back surface 32 of the substrate 51 (FIG. 17(b)). The lens 71 illustrated in FIG. 17(b) is the lens 14 having a conical shape (axicon lens).

Thereafter, the substrate 51 is laminated on the substrate 61 with the bumps 48 interposed therebetween (see B of FIG. 4). In this way, the light emitting device 1 according to the present embodiment is manufactured. Note that the lens 71 of this example may include a lens other than an axicon lens.

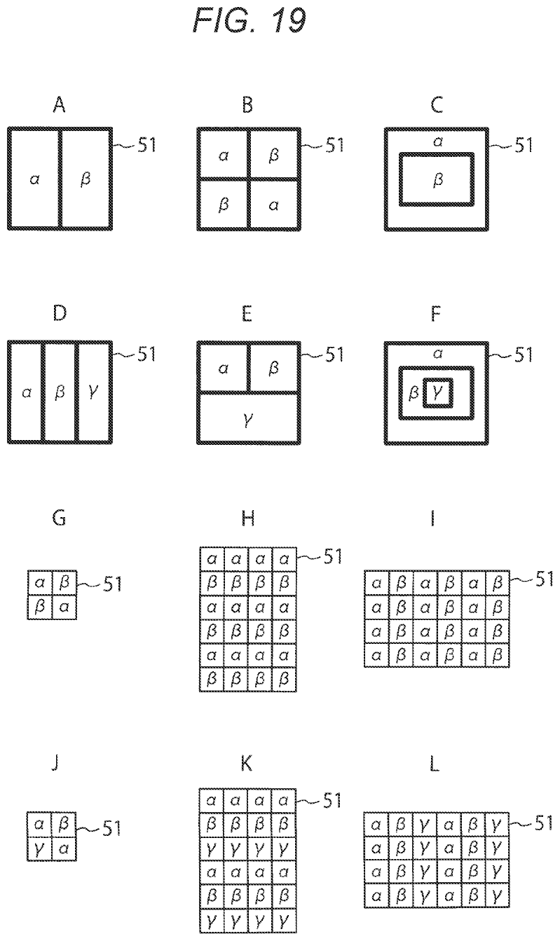

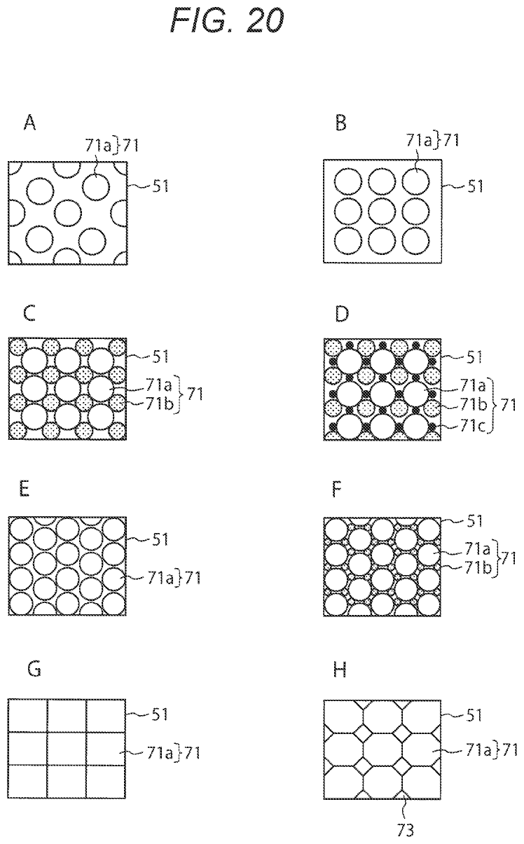

Next, the arrangement of the lens 71 according to the present embodiment will be described with reference to FIGS. 19 and 20.

FIG. 19 is a plan view illustrating an example of. the arrangement of the lens 71 according to the first embodiment.

In A to L of FIG. 19, a reference sign a indicates a region where the lens 71 of a first type (for example, a spherical lens) is arranged at the back surface S2 of the substrate 51. A reference sign indicates a region. where the lens 71 of a second type (for example, an axicon lens) is arranged at the back surface S2 of the substrate 51. A reference sign γ indicates a region where the lens 71 of a third type (for example, a pyramidal lens) is arranged at the back surface S2 of the substrate 51. Hereinafter, these regions are referred to as spherical region α″, “conical region p”, and “pyramidal region γ”.

In A of FIG. 19, the back surface S2 of the substrate 51 is divided into two regions. One region is the spherical region α, and the other region is the conical region β. For example, in a case where N×M lenses 71 are arranged at the back surface S2 of the substrate 51, the spherical region α includes (N/2)×N lenses 71, and the conical region β includes (N/2)×N lenses 71 (N and M are integers of two or more). Similarly, in B of FIG. 19, the back surface S2 of the substrate 51 is divided into four regions, and in C of FIG. 19, the back surface S2 of the substrate 51 is divided into two regions.

In D of FIG. 19, the back surface 52 of the substrate 51 is divided into three regions, and these regions are the spherical region α, the conical region 13, and the pyramidal region γ. For example, in a case where N×M lenses 71 are arranged at the back surface S2 of the substrate 51, the spherical region a includes (N/3)×N lenses 71, the conical region β includes (N/3)×M lenses 71, and the pyramidal region γ includes (N/3)×M lenses 71. Similarly, in F, of FIG. 19, the back surface 52 of the substrate 51 is divided into three regions, and in F of FIG. 19, the back surface S2 of the substrate 51 is divided into three regions.

In A to F of FIG. 19, the back surface S2 of the substrate 51 is divided into several regions. On the other hand, in G to L of FIG. 19, the back surface S2 of the substrate 51 is subdivided into a large number of regions.

G of FIG. 19 illustrates a region for four lenses 71 in the back surface S2 of the substrate 51. In the example illustrated in G of FIG. 19, this region is divided into two spherical regions e and two conical regions 5. In G of FIG. 19, each spherical region α includes one lens 71, and each conical region β includes one lens 71. The light emitting device 1 of this example includes a plurality of unit regions at the back surface S2 of the substrate 51. Each unit region has a structure illustrated in G of FIG. 19. That is, in the light emitting device 1 of this example, the structure illustrated in G of FIG. 19 is repeated in the X direction (lateral direction of G of FIG. 19) and the Y direction (longitudinal direction of G of FIG. 19).

This similarly applies to H to L of FIG. 19. For example, in the example illustrated in H of FIG. 19, the structure illustrated in H of FIG. 19 is repeated in the X direction and the Y direction.

Note that the structures illustrated in A to F of FIG. 19 have an advantage that wiring lines in the LDD substrate 42 can be easily laid out, for example. On the other hand, the structures illustrated in G to L of FIG. 19 have an advantage that the positional deviation of light can be suppressed, for example.

FIG. 20 is a plan view illustrating an example of the arrangement of the lens 71 according to the first embodiment.

The lens 71 illustrated in A of FIG. 20 includes only a main lens 71a. The main lens 71a illustrated in A of FIG. 20 is, for example, a spherical lens. These main lenses 71a are arranged in a square lattice inclined with respect to the X direction (lateral direction of A of FIG. 20) and the Y direction (longitudinal direction of A of FIG. 20).

The lens 71 illustrated in B of FIG. 20 also includes only the main lens 71a. The main lens 71a illustrated in B of FIG. 20 is, for example, an axicon lens. These main lenses 71a are arranged in a square lattice parallel to the X direction and the Y direction.

The lens 71 illustrated in C of FIG. 20 includes a sub-lens 71b smaller than the main lens 71a in addition to the main lens 71a illustrated in B of FIG. 20. The sub-lens 71b illustrated in C of FIG. 20 is, for example, a spherical lens. According to this example, the light emitting device 1 having the similar workings as the a forementioned light emitting device 1 according to the first modified example can be realized. The sub-lenses 71b illustrated in C of FIG. 20 are arranged in a square lattice in gaps between the main lenses 71a.

The lens 71 illustrated in D of FIG. 20 includes a sub-lens 71c smaller than the sub-lens 71b in addition to the main lens 71a and the sub-lens 71b illustrated in C of FIG. 20. The sub-lens 71c illustrated in D of FIG. 20 is, for example, a pyramidal lens. According to this example, for example, light having uniformity of illuminance better than that of the aforementioned light according to the first modified example can be obtained. The sub-lenses 71c illustrated in D of FIG. 20 are arranged in a square lattice in gaps between the main lenses 71a and the sub-lens 71b.

The lens 71 illustrated in E of FIG. 20 includes only the main lens 71a. The main lens 71a illustrated in F of FIG. 20 is, for example, an axicon lens. These main lenses 71a are arranged in a hexagonal close-packed lattice.

The lens 71 illustrated in. F of FIG. 20 includes the sub-lens 71b smaller than the main lens 71a in addition to the main lens 71a illustrated in F of FIG. 20. The sub-lens 71b illustrated in F of FIG. 20 is, for example, a spherical lens. According to this example, the light emitting device 1 having the similar workings as the aforementioned light emitting device 1 according to the first modified example can be realized. The sub-lenses 71b illustrated in F of FIG. 20 are arranged in. gaps between the main lenses 71a.

The lens 71 illustrated in G of FIG. 20 includes only the main lens 71a. The main lens 71a illustrated in. G of FIG. 20 is, for example, a quadrangular pyramidal lens. These main lenses 71a are arranged in a fly-eye arrangement.

The lens 71 illustrated in H of FIG. 20 includes only the main lens 71a, similarly to the lens 71 in G of FIG. 20. The light emitting device 1 of this example further includes a facet portion 73 having a plurality of facets between the main lenses 71a. As a result, the main lens 71a illustrated in H of FIG. 20 is, for example, an octagonal pyramidal lens. The facet portion 73 of this example has a concave pyramid shape, and has a working of scattering light without causing light to travel straight.

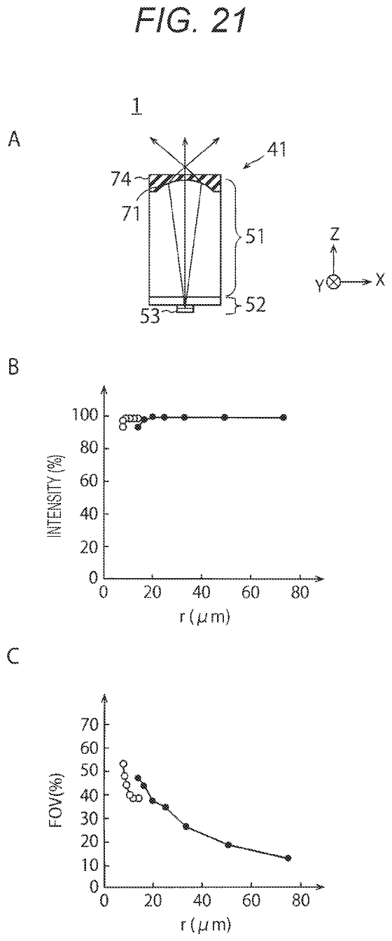

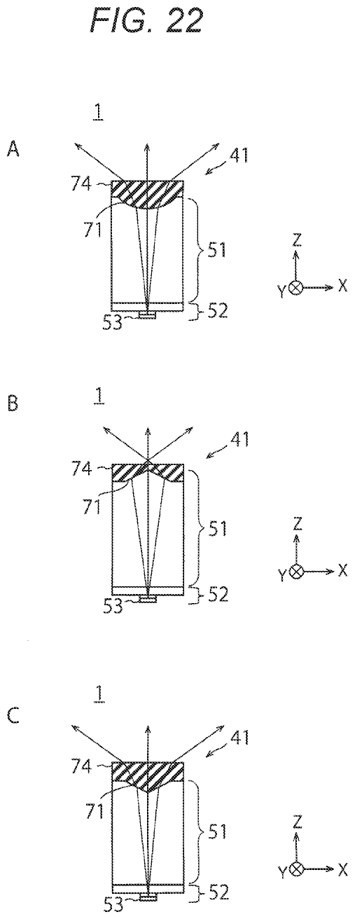

Next, the workings of the lens 71 according to the present embodiment will be described with reference to FIGS. 21 and 22.

FIG. 21 is a cross-sectional view and a graph for explaining the workings of the lens 71 according to the first embodiment.

A of FIG. 21 illustrates one of a plurality of the lenses 71 of the light emitting device 1 illustrated in A of FIG. 14, and specifically, illustrates the lens L1 (convex spherical lens). In the example illustrated in A of FIG. 21, the light emitting device 1 includes a refractive index buffer layer 74 formed at the back surface S2 of the substrate 51. The refractive index buffer layer 74 according to the present embodiment is formed at substantially the entire back surface S2 of the substrate 51 and covers each lens 71. Furthermore, the refractive index buffer layer 74 according to the present embodiment has a flat upper surface, and this upper surface is exposed to air.

The refractive index buffer layer 74 is formed to reduce a change in refractive index from the inside to the outside of the substrate 51. Therefore, the refractive index of the refractive index buffer layer 74 is set to be lower than the refractive index of the substrate 51, and here, is set to a value between the refractive index of the substrate 51 and the refractive index of air. In the present embodiment, the substrate 51 is a GaAs substrate, and the refractive index of the substrate 51 is 3.55. Therefore, the refractive index of the refractive index buffer layer 74 according to the present embodiment is set to be lower than 3.55. The refractive index buffer layer 74 according to the present embodiment is, for example, a silicon nitride (SiN) film.

In A of FIG. 21, a path of light refracted by the lens 71 and the refractive index buffer layer 74 is indicated by arrows. In A of FIG. 21, in a case where light emitted from the lens 71 is inclined with respect to the Z direction, the inclination of this light with respect to the Z direction is further increased when this light is emitted from the refractive index buffer layer 74. This has a working of widening the field of view (FOV) of the distance measuring device.

In A and C1 of FIG. 21, a simulation result in a case where the refractive index buffer layer 74 is provided on the lens 71 in A of FIG. 21 is indicated by a white circle, and a simulation result in a case where the refractive index buffer layer 74 is not provided on the lens 71 in A of FIG. 21 is indicated by a black circle. The horizontal axes in B and C of. FIG. 21 indicate the radius of curvature r of the lens 71. The vertical axis in B of FIG. 21 indicates the intensity of light transmitted through the lens 71 and the refractive index buffer layer 74 (white circle) and the intensity of light transmitted through the lens 71 (black circle). The vertical axis in C of FIG. 21 indicates the field of view of the distance measuring device with light transmitted through the lens 71 and the refractive index buffer layer 74 (white circle), and the field of view of the distance measuring device with light transmitted through the lens 71 (black circle).

According to B and C of FIG. 21, it can be seen that when the refractive index buffer layer 74 is provided on the lens 71, total reflection can be suppressed even if the radius of curvature r of the lens 71 is small, and a sufficient field of view can be secured even if the radius of curvature r of the lens 71 is small. With this configuration, the lens 71 can be miniaturized and the degree of integration of the lens 71 can be increased.

FIG. 22 is a cross-sectional view for explaining the workings of the lens 71 according to the first embodiment.

A of FIG. 22 illustrates one of a plurality oil the lenses 71 of the light emitting device 1 illustrated in

FIG. 15, and specifically, illustrates the lens L3 (concave spherical lens). B of FIG. 22 illustrates one of a plurality of the lenses 71 of the light emitting device 1 illustrated in A of FIG. 14, and specifically, illustrates the lens 12 (convex axicon lens). C of FIG. 22 illustrates one of a plurality of the lenses 71 of the light emitting device 1 illustrated in FIG. 15, and specifically, illustrates the lens 14 (concave axicon lens). Also in the example illustrated in each of A to C of FIG. 22, the light emitting device 1 includes the refractive index buffer layer 74 formed at the back surface S2 of the substrate 51.

In A to C of FIG. 22, a path of light refracted by the lens 71 and the refractive index buffer layer 74 is indicated by arrows. In A to C of FIG. 22, in a case where light emitted from the lens 71 is inclined with respect to the Z direction, the inclination of this light with respect to the Z direction is further increased when this light is emitted from the refractive index buffer layer 74. This has a working of widening the field of view of the distance measuring device, similarly to the case of A of FIG. 21. Therefore, the content that has been described with reference to the graphs in B and C of FIG. 21 also applies to the lenses 71 in A to C of FIG. 22.

Note that the refractive index buffer layer 74 according to the present embodiment may be applied to the light emitting device 1 other than the light emitting device 1 illustrated in A of FIG. 14 or FIG. 15. For example, the refractive index buffer layer 74 according to the present embodiment may be applied to the light emitting device 1 illustrated in any of A of FIG. 4, B of FIG. 4, A of FIG. 7, and A of FIG. 12.

As described above, the light emitting device 1 according to the present embodiment includes a plurality of the lenses 71 provided at the substrate 51, and these lenses 71 include at least a lens other than the spherical lens and the ellipsoidal lens. For example, these lenses 71 include a first lens that is an axicon lens, a pyramidal lens, a hyperboloid lens, a parabolic lens, or a Fresnel lens, and a second lens that is a spherical lens or an ellipsoidal lens.

Therefore, according to the present embodiment, light from a plurality of the light emitting elements 53 can be more suitably formed by these lenses 71. For example, light from a plurality of the light emitting elements 53 can be formed into light having low illuminance at the central portion instead of light having high illuminance at the central portion, and can be formed into light having good uniformity of illuminance.

(Second Embodiment)

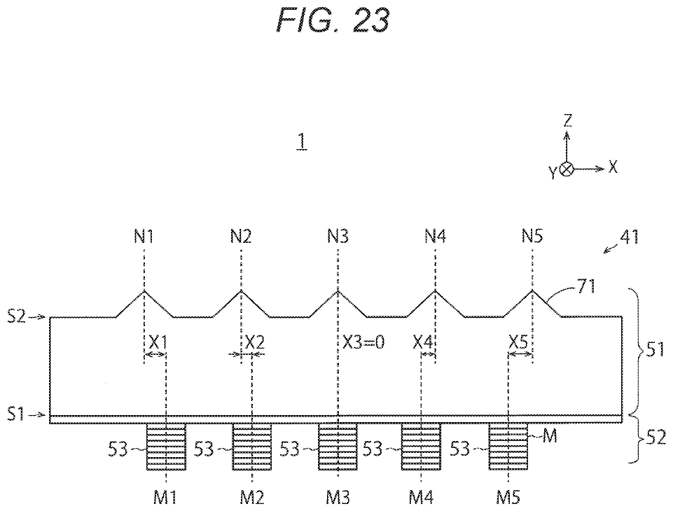

FIG. 23 is a cross-sectional view illustrating a structure of the light emitting device 1 according to a second embodiment.

FIG. 23 illustrates the light emitting device 1 in which the lens 71 and the light emitting element 53 have a one-to-one correspondence, similarly to A of FIG. 4. Each lens 71 illustrated in FIG. 23 is provided above the corresponding one light emitting element 53, and therefore receives light emitted from the corresponding one light emitting element 53. FIG. 23 illustrates five of a plurality of the light emitting elements 53 provided at the front surface S1 of the substrate 51 and five of a plurality of the lenses 71 provided at the back surface S2 of the substrate 51.

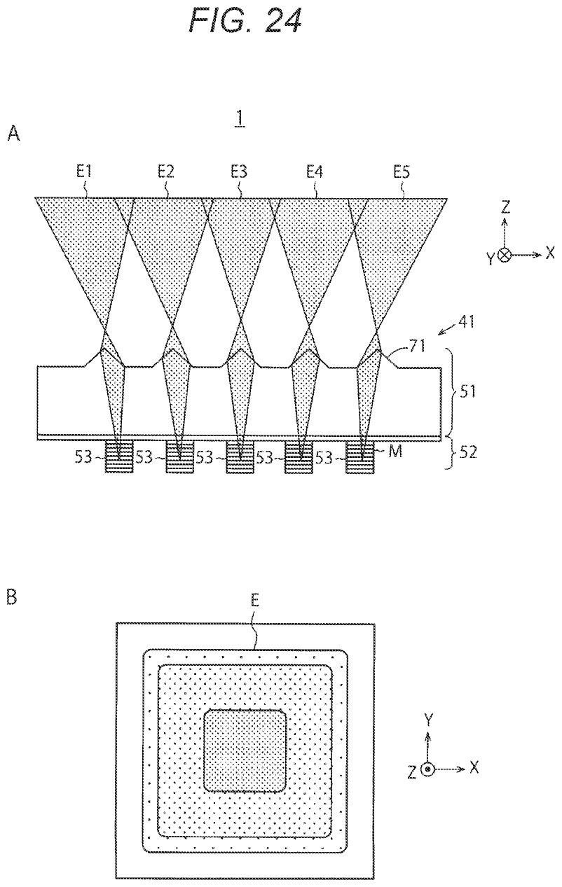

However, in the present embodiment, the position of the optical axis of each lens 71 does not necessarily. coincide with the position of the optical axis of the corresponding light emitting element 53. FIG. 24 illustrates optical axes N1 to N5 of the five lenses 71, optical axes M1 to M5 of the five light emitting elements 53, and amounts of misalignment X1 to X5 between the positions of the optical axes N1 to N5 and the positions of the optical axes M1 to M5. The lenses 71 having the optical axes N1 to N5 correspond to the light emitting. elements 53 having the optical axes M1 to 915, respectively. The lens 71 having the optical axis N3 is located at the center of the plurality of lenses 71 described above.

The position of the optical axis of each lens 71 according to the present embodiment is misaligned from the position of the optical axis of the corresponding light emitting element 53 except for the lens 71 located at the center. Specifically, the position of the optical axis of each lens 71 according to the present embodiment is misaligned from the position of the optical axis of the corresponding light emitting element 53 in a direction away from the center. For example, the optical axes N1 and N2 are misaligned in the −X direction with respect to the optical axes M1 and M2, respectively. Furthermore, the optical axes N4 and N5 are misaligned in the +X direction with respect to the optical axes M4 and M5, respectively. Such a misalignment of the optical axis has a working of widening the field of view (FEW) of the distance measuring device. This will be described with reference to FIG. 24.

FIG. 24 is a cross-sectional view and a plan view illustrating the operation of the light emitting device 1 according to the second embodiment.

A of FIG. 24 illustrates the way in which the light E1 to the light E5 emitted from the light emitting element 53 of the light emitting device 1 illustrated in FIG. 23 spread. The light E1 and the light E2 are emitted biased in the −X direction by the corresponding lens 71. On the other hand, the light E4 and the light E5 are emitted biased in the +X direction by the corresponding lens 71. With this configuration, the field of view of the distance measuring device can be widened

B of FIG. 24 illustrates the illuminance distribution of the light B in the XY plane above these lenses 71, similarly to B of FIG. 7, B of FIG. 12, B of FIG. 13, and the like. In B of FIG. 24, a region where illuminance is low is denoted by a sparse dot group, a region where illuminance is high is denoted by a dense dot group, and a region where illuminance is in a medium degree is denoted by a dot group having medium-degree density.

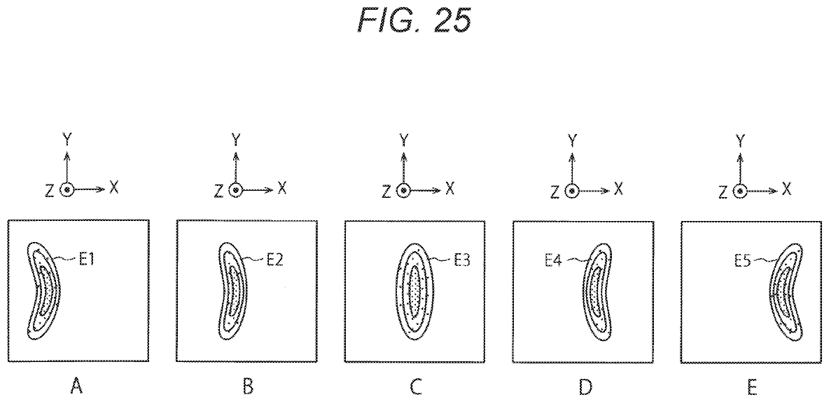

The light emitting device 1 according to the present embodiment may be used in, for example, an aspect. as illustrated in FIG. 25. Hereinafter, an operation example of the light emitting device 1 according to the present embodiment will be described with reference to FIG. 25.

FIG. 25 is a plan view for explaining an operation example of the light emitting device 1 according to the second embodiment.

A of FIG. 25 illustrates an illuminance distribution in a case where only the light E1 among the light E1 to the light E5 illustrated in A of FIG. 24 is caused to be emitted. Similarly, B to E of FIG. 25 respectively illustrate illuminance distributions in a case where only one of the light E2 to the light E5 among the light E1 to the light ES illustrated in A of FIG. 24 is caused to emit light.

In this example, the light emitting device 1 sequentially drives the plurality of light emitting elements 53 described above by one column. Specifically, one column of the light emitting elements 53 including the first light emitting element 53 from the left in A of FIG. 24 is first driven, and then one column of the light emitting elements 53 including the second light emitting element 53 from the left in A of FIG. 24 is driven. Thereafter, one column of the light emitting elements 53 including the third light emitting element 53 from the left, one column of The light emitting elements 53 including the fourth light emitting element 53 from the left, and one column of the light emitting elements 53 including the fifth light emitting element 53 from the left are sequentially driven. Note that each of these columns includes a plurality of the light emitting elements 53 adjacent to each other in the Y direction. The control as described above is performed by the aforementioned LDD substrate 42 (drive circuit 12).

As a result of such control, the light emitting device 1 sequentially emits the light E1 to the light E5 from the lens 71 to a subject (FIG. 1). Therefore, the subject is first irradiated with the light E1, then irradiated with the light E2, and thereafter, is sequentially irradiated with the light E3 to the light E5. With this configuration, the subject can be scanned. with the light E1 to the light E5. In general, the distance measuring device can perform power-saving driving due to selective light irradiation by scanning with line light moving on the subject, thereby making it possible to promote heat dissipation. According to the present embodiment, such scanning with the line light can be performed by using the light E1 to the light E5.

Note that the control according to the present. embodiment may be applied not only to the light emitting device 1 including only an axicon lens as in A of FIG. 23, but also to the light emitting device 1 including only a spherical lens as well as the light emitting device 1 including an axicon lens and a spherical lens in this case, the axicon lens may be replaced with a pyramidal lens, a hyperboloid lens, a parabolic lens, or a Fresnel lens, and the spherical lens may be replaced with an ellipsoidal lens.

(Third Embodiment)

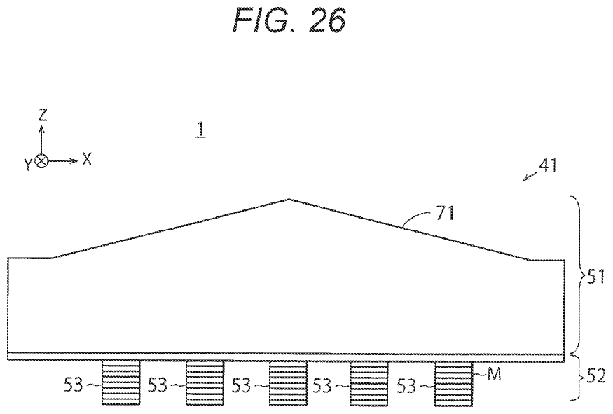

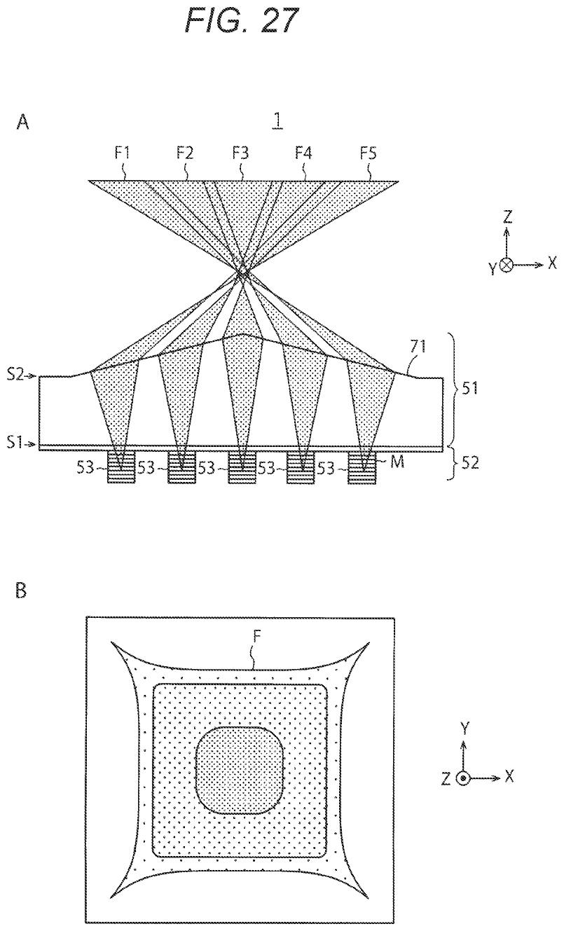

FIG. 26 is a cross-sectional view illustrating a structure of the light emitting device 1 according to a third embodiment.

FIG. 26 illustrates the light emitting device 1 in which the lens 71 and the light emitting element. 53 have a one-to-m correspondence (m is an integer of two or more). The lens 71 illustrated in FIG. 26 is provided above a corresponding plurality of the light emitting elements 53, and therefore receives light emitted from a corresponding plurality of the light emitting elements 53. FIG. 26 illustrates five of a plurality of the light emitting elements 53 provided at the front surface S1 of the substrate 51 and one of the one or more lenses 7 provided at the back surface S2 of the substrate 51.

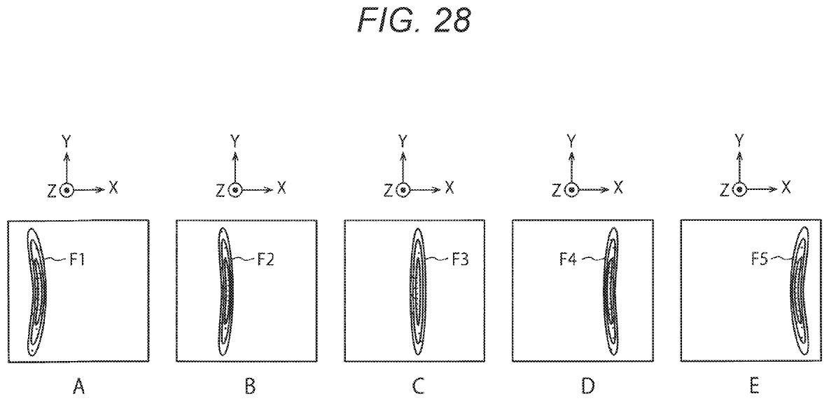

As described above, the lens 71 according to the present embodiment corresponds to the light emitting element 53 on a one-to-m basis. Such a lens 71 has a working of widening the field of view (FOV) of the distance measuring device, similarly to the misalignment of the optical axis according to the second embodiment. This will be described with reference to FIG. 27.

FIG. 27 is a cross-sectional view and a plan view illustrating the operation of the light emitting device 1 according to the third embodiment.

A of FIG. 27 illustrates the way in which light F1 to light F5 emitted from the light emitting element 53 of the light emitting device 1 illustrated in FIG. 26 spread. The light F1 and the light F2 are emitted biased in the −X direction by the slope on the right side of the lens 71. On the other hand, the light F4 and the light

F5 are emitted biased in the +X direction by the slope on the left side of the lens 71. With this configuration, the field of view of the distance measuring device can be widened

B of FIG. 27 illustrates the illuminance distribution of the light F in the XY plane above the lenses 71, similarly to B of FIG. 7, B of FIG. 12, B of FIG. 13, and the like in B of FIG. 27, a region where illuminance is low is denoted by a sparse dot group, a region where illuminance is high is denoted by a dense dot group, and a region where illuminance is in a medium. degree is denoted by a dot group having medium-degree density.

The light emitting device 1 according to the present embodiment may be used in, for example, an aspect as illustrated in FIG. 28. Hereinafter, an operation example of the light emitting device 1 according to the present embodiment will be described with reference to FIG. 28.

FIG. 28 is a plan view for explaining an operation example of the light emitting device 1 according to the third embodiment.

A of FIG. 28 illustrates an illuminance distribution in a case where only the light F1 among the light F1 to the light F5 illustrated in A of FIG. 27 is caused to be emitted. Similarly, B to E of FIG. 28 respectively illustrate illuminance distributions in a case where only one of the light F2 to the light F5 among the light F1 to the light F5 illustrated in A of FIG. 27 is caused to emit light.

In this example, the light emitting device 1 sequentially drives the plurality of light emitting elements 53 described above by one column. Specifically, one column of the light emitting elements 53 including the first light emitting element 53 from the right in A of FIG. 27 is first driven, and then one column of the light emitting elements 53 including the second light emitting element 53 from the right in A of FIG. 27 is driven. Thereafter, one column of the light emitting elements 53 including the third light emitting element 53 from the right, one column of the light emitting elements 53 including the fourth light emitting element 53 from the right, and one column of the light emitting elements 53 including the fifth light emitting element 53 from the right are sequentially driven. Note that each of these columns includes a plurality of the light emitting elements 53 adjacent to each other in the Y direction.

The control as described above is performed by the aforementioned LDD substrate 42 (drive circuit 12).

As a result of such control, the light emitting device 1 sequentially emits the light F1 to the light F5 from the lens 71 to a subject (FIG. 1). Therefore, the subject is first irradiated with the light F1, then irradiated with the light F2, and thereafter, is sequentially irradiated with the light F3 to the light 5. With this configuration, the subject can be scanned with the light P1 to the light F5 in general, the distance measuring device can perform power-saving driving due to selective Light irradiation by scanning with line light moving on the subject, thereby making it possible to promote heat dissipation. According to the present embodiment, such scanning with the line light can be performed by using the light F1 to the light F5.

Note that the control according to the present embodiment may be applied not only Co the light emitting device 1 including only an axicon lens as in A of FIG. 26, but also to the light emitting device 1 including only a spherical lens as well as the light emitting device 1 including an axicon lens and a spherical lens. In this case, the axicon lens may be replaced with a pyramidal lens, a hyperboloid lens, a parabolic lens, or a Fresnel lens, and the spherical lens may be replaced with an ellipsoidal lens.

Note that the light emitting devices 1 according to the first to third embodiments are each used as a light source of a distance measuring device, but may be used in other aspects. For example, the light emitting devices 1 according to these embodiments each may be used as a light source of an optical instrument such as a printer, or may be used as a lighting device. Furthermore, the lenses 71 according to the first to third embodiments are each provided at the back surface S2 of the substrate 51 as a part of the substrate 51, but may be provided at the back surface S2 of the substrate 51 as a part of a film formed on the substrate 51.

Although the embodiments of the present disclosure have been described above, these embodiments may be implemented with various alterations without departing from the spirit of the present disclosure. For example, two or more embodiments may be implemented in combination.

Note that the present disclosure can also have the following configurations.

(1)

A light emitting device including:

a substrate;

a plurality of light emitting elements provided at a first surface of the substrate; and

a plurality of lenses provided at a second surface of the substrate, in which the plurality of lenses includes a first lens other than a spherical lens and an ellipsoidal lens.

(2)

The light emitting device according to (1), in which the first lens includes a lens having a single zone.

(3)

The light emitting device according to (1), in which the first lens includes an axicon lens, a pyramidal lens, a hyperboloid lens, or a parabolic lens.

(4)

The light emitting device according to (1), in which the first lens has a shape having an apex.

(5)

The light emitting device according to (1), in which the first lens is a lens having a plurality of zones.

(6)

The light emitting device according to (1), in which the first lens is a Fresnel lens.

(7)

The light emitting device according to (1), in which the plurality of lenses includes the first lens other than a spherical lens and as ellipsoidal lens, and a second lens having a shape different from a shape of the first lens.

(8)

The light emitting device according to (7), is which the second lens includes a spherical lens or an ellipsoidal lens.

(9)

The light emitting device according to (1), is which the plurality of lenses has a structure that does not cause light from the light emitting element to be totally reflected.

(10)

The light emitting device according to (1), in which the plurality of lenses includes at least any of a convex lens or a concave lens.

(11)

The light emitting device according to (1), in which light emitted from one of the plurality of light emitting elements is incident on one corresponding lens.

(12)

The light emitting device according to (1), is which light emitted from one of the plurality of light emitting elements is incident on a corresponding plurality of lenses.

(13)

The light emitting device according to (1), further including a refractive index buffer layer provided at the second surface of the substrate to cover the plurality of lenses, the refractive index buffer layer having a refractive index lower than a refractive index of the substrate.

(14)

The light emitting device according to (1), further including a drive device configured to drive the plurality of light emitting elements to cause the plurality of light emitting elements to emit light.

(15)

The light emitting device according to (14), in which the drive device is provided on the first surface side of the substrate with the plurality of light emitting elements interposed between the drive device and the substrate.

(16)

The light emitting device according to (14), is which the drive device drives the plurality of light emitting elements for each individual light emitting element.

(17)

The light emitting device according to (14), in which the drive device scans a subject with light from the plurality of light emitting elements by sequentially driving the plurality of light emitting elements.

(18)

The light emitting device according to (17),

in which one of the plurality of lenses receives light emitted from one corresponding light emitting element, and

a position of an optical axis of at least any of lenses is misaligned from a position of an optical axis of a corresponding light emitting element.

(19)

The light emitting device according to (17), in which one of the plurality of lenses receives light emitted from a corresponding plurality of light emitting elements.

(20)

A method of manufacturing a light emitting device including:

forming a plurality of light emitting elements at a first surface of a substrate; and

forming a plurality of lenses at a second surface of the substrate,

in which the plurality of lenses includes a first lens other than a spherical lens and an ellipsoidal lens.

(21)

The method of manufacturing a light emitting device according to (20), in which the plurality of lenses is formed at the second surface of the substrate by etching processing, laser processing, or electron beam processing.

(22)

A distance measuring device including:

a light emitting device configured to irradiate a subject with light;

an imaging device configured to receive light reflected by the subject, to image the subject; and

a control device configured to measure a distance to the subject using an image signal output from the imaging device,

in which the light emitting device includes a substrate,

a plurality of light emitting elements provided at a first surface of the substrate, the plurality of light emitting elements configured to emit the light, and a plurality of lenses provided at a second surface of the substrate, the plurality of lenses configured to form the light, and

the plurality of lenses includes a first lens other than a spherical lens and an ellipsoidal lens.

### REFERENCE SIGNS LIST

1 Light emitting device
2 Imaging device
3 Control device
11 Light emitting unit
12 Drive circuit
13 Power supply circuit
14 Light-emission-side optical system.
21 Image sensor
22 Image processing unit
23 Imaging-side optical system
31 Distance measuring unit
41 LD chip
42 LDD substrate
43 Mounting substrate
44 Heat dissipating substrate
45 Correction lens holder
46 Correction lens
47 Wiring line
48 Bump
51 Substrate
52 Laminated film
53 Light emitting element
54 Anode electrode
55 Cathode electrode
61 Substrate
62 Connection pad
71 Lens
71a Main lens
71b Sub-lens
71c Sub-lens
72 Resist film
13 Facet portion
74 Refractive index buffer layer

1. A light emitting device comprising:
a substrate;
a plurality of light emitting elements provided at a first surface of the substrate; and
a plurality of lenses provided at a second surface of the substrate,
wherein the plurality of lenses includes a first lens other than a spherical lens and an ellipsoidal lens.

2. The light emitting device according to claim 1, wherein the first lens includes a lens having a single zone.

3. The light emitting device according to claim 1, wherein the first lens includes an axicon lens, a pyramidal lens, a hyperboloid lens, or a parabolic lens.

4. The light emitting device according to claim 1, wherein the first lens has a shape having an apex.

5. The light emitting device according to claim 1, wherein the first lens is a lens having a plurality of zones.

6. The light emitting device according to claim 1, wherein the first lens is a Fresnel lens.

7. The light emitting device according to claim 1, wherein the plurality of lenses includes the first lens other than a spherical lens and an ellipsoidal lens, and a second lens having a shape different from a shape of the first lens.

8. The light emitting device according to claim 7, wherein the second lens includes a spherical lens or an ellipsoidal lens.

9. The light emitting device according to claim 1, wherein the plurality of lenses has a structure that does not cause light from the light emitting element to be totally reflected.

10. The light emitting device according to claim 1, wherein the plurality of lenses includes at least any of a convex lens or a concave lens.

11. The light emitting device according to claim 1, wherein light emitted from one of the plurality of light emitting elements incident on one corresponding lens.

12. The light emitting device according to claim 1, wherein light emitted from one of the plurality of light emitting elements is incident on a corresponding plurality of lenses.

13. The light emitting device according to claim 1, further comprising a refractive index buffer layer provided at the second surface of the substrate to cover the plurality of lenses, the refractive index buffer layer having a refractive index lower than a refractive index of the substrate.

14. The light emitting device according to claim 1, further comprising a drive device configured to drive the plurality of light emitting elements to cause the plurality of light emitting elements t.o emit light.

15. The light emitting device according to claim 14, wherein the drive device is provided on the first surface side of the substrate with the plurality of light emitting elements interposed between the drive device and the substrate.

16. The light emitting device according to claim 14, wherein the drive device drives the plurality of light emitting elements for each individual light emitting. element.

17. The light emitting device according to claim 14, wherein the drive device scans a subject with light from the plurality of light emitting elements by sequentially driving the plurality of light emitting elements.

18. The light emitting device according t.o claim 17,
wherein one of the plurality of lenses receives light emitted from one corresponding light emitting element, and
a position of an optical axis of at least any of lenses is misaligned from a position of an optical axis of a corresponding light emitting element.

19. The light emitting device according to claim 17, wherein one of the plurality of lenses receives light emitted from a corresponding plurality of light emitting elements.

20. A distance measuring device comprising:
a light emitting device configured to irradiate a subject with light;
an imaging device configured to receive light reflected by the subject, to image the subject; and
a control device configured to measure a distance to the subject using an image signal output from the imaging device,
wherein the light emitting device includes
a substrate,
a plurality of light emitting elements provided at a first surface of the substrate, the plurality of light emitting elements configured to emit the light, and
a plurality of lenses provided at a second surface of the substrate, the plurality of lenses configured to form the light, and
the plurality of lenses includes a first lens other than a spherical lens and an ellipsoidal lens.
